(19) United States
(12) Patent Application Publication
(10) Pub. No.: US 2026/0157195 A1
(43) Pub. Date: Jun. 4, 2026

(54) SEMICONDUCTOR PACKAGE

(71) Applicant: Samsung Electronics Co., Ltd., Suwon-si (KR)

(72) Inventor: Byeonguk Jeon, Suwon-si (KR)

(21) Appl. No.: 19/398,282

(22) Filed: Nov. 24, 2025

(30) Foreign Application Priority Data
Dec. 2, 2024 (KR) 10-2024-0176878
Mar. 6, 2025 (KR) 10-2025-0029202

(51) Int. Cl. H10W 70/60; H10B 80/00

(52) U.S. Cl. CPC H10W 70/611; H10B 80/00; H10W 70/65; H10W 90/10; H10W 90/24

(57) ABSTRACT

A semiconductor package includes a package substrate, a first controller on the package substrate, a second controller on the package substrate and spaced apart from the first controller chip, and first substrate pads and first signal line patterns at an upper surface of the package substrate and connected to the first controller, wherein at least part of each signal line of the first signal line patterns extends along a second direction perpendicular to the first direction in an area between the first controller and the second controller.

### CROSS-REFERENCE TO RELATED APPLICATION

This application is based on and claims priority under 35 U.S.C. § 119 to Korean Patent Application Nos. 10-2024-0176878, filed on Dec. 2, 2024, and 10-2025-0029202, filed on Mar. 6, 2025, in the Korean Intellectual Property Office, the disclosures of which are incorporated by reference herein in their entireties.

### BACKGROUND

Aspects of the inventive concept relate to a semiconductor package.

Non-volatile memory may retain stored data even when power is cut off. Flash-based non-volatile memory may be used for storing or moving large amounts of data in a storage device such as an embedded multi-media card (eMMC), a universal flash storage (UFS), a solid state drive (SSD), a memory card, or the like.

A storage device may be implemented with a semiconductor package including a plurality of non-volatile memory chips and a controller chip. The plurality of non-volatile memory chips may be allocated to one or more channels and connected to the controller chip.

To enhance the signal integrity of semiconductor devices, differential signals may be used. For transmitting differential signals, input signals and their complementary signals having opposite phases may be transmitted together using a pair of adjacent wiring patterns. The differential signals may cancel off signal noise generated from operation of the storage device.

### SUMMARY

Aspects of the inventive concept provide a semiconductor package with enhanced data processing performance and an optimized wiring rate.

Also, the objectives to be achieved by the technical spirit of the inventive concept are not limited to the objectives mentioned above, and other objectives can be clearly understood by one of ordinary skill in the art from the following description.

According to an aspect of the inventive concept, a semiconductor package includes a package substrate, a first controller on the package substrate, a second controller on the package substrate and spaced apart from the first controller chip, and first substrate pads and first signal line patterns at an upper surface of the package substrate and connected to the first controller, wherein at least part of each signal line of the first signal line patterns extends along a second direction perpendicular to the first direction in an area between the first controller and the second controller.

According to another aspect of the inventive concept, a semiconductor package includes a package substrate, a first controller chip and a second controller chip on an upper surface of the package substrate and spaced apart from each other in a first direction; a first semiconductor chip stack on the upper surface of the package substrate, a second semiconductor chip stack spaced apart from the first semiconductor chip stack and on the upper surface of the package substrate, first substrate pads and first signal line patterns at the upper surface of the package substrate and connected to the first controller chip; and external connection terminals provided on a lower surface of the package substrate and connected to the first signal line patterns. The first semiconductor chip stack includes two or more first memory chips, and the second semiconductor chip stack includes two or more second memory chips, and each first memory chip is connected to at least one of the first substrate pads. In an area between the first controller chip and the second controller chip, the first signal line patterns extend in a second direction perpendicular to the first direction.

According to another aspect of the inventive concept, a semiconductor package includes a package substrate, a first controller chip and a second controller chip mounted on the package substrate in a flip-chip bonding structure through bumps and being adjacent to each other in a first direction, a first semiconductor chip stack and a second semiconductor chip stack spaced apart from each other and from an area between the first controller chip and the second controller chip on the package substrate, first substrate pads and first signal line patterns at an upper surface of the package substrate and connected to bumps of the first controller chip, second substrate pads and second signal line patterns at the upper surface of the package substrate and connected to bumps of the second controller chip, and external connection terminals on a lower surface of the package substrate and connected to the first signal line patterns and the second signal line patterns. The first signal line patterns and the second signal line patterns are each configured to transmit radio frequency signals in a range of 6 Ghz to 100 Ghz, and in the area between the first controller chip and the second controller chip, the first signal line patterns and the second signal line patterns each extend in a second direction perpendicular to the first direction.

### BRIEF DESCRIPTION OF THE DRAWINGS

Embodiments will be more clearly understood from the following detailed description taken in conjunction with the accompanying drawings in which:

FIG. 1 is a block diagram illustrating a storage system including a semiconductor package according to embodiments;

FIG. 2 is a block diagram illustrating a host device;

FIG. 3 is a block diagram illustrating a storage device including a semiconductor package according to embodiments;

FIG. 4 is a block diagram illustrating a storage system including a semiconductor package according to embodiments;

FIG. 5 is a cross-sectional view schematically illustrating a semiconductor package according to embodiments;

FIG. 6 is a plan view schematically illustrating a semiconductor package according to embodiments;

FIG. 7 is a plan view schematically illustrating a semiconductor package according to embodiments;

FIG. 8 is a plan view schematically illustrating a semiconductor package according to embodiments; and

FIG. 9 is a plan view schematically illustrating a semiconductor package according to embodiments.

### DETAILED DESCRIPTION OF THE EMBODIMENTS

Hereinafter, embodiments will be described in detail with reference to the accompanying drawings. Like reference symbols are used for like elements in the drawings, and redundant descriptions thereof are omitted.

In the following embodiments, ordinal numbers such as “first,” “second,” etc. may be used for the purpose of distinguishing one element from other elements, not a limited sense. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise.

It will be understood that when an element is referred to as being “connected” to or “on” another element, it can be directly connected to or on the other element or intervening elements may be present.

Spatially relative terms, such as “lower,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures.

In various embodiments of the present specification, a “first direction” refers to a first horizontal direction (e.g., X-direction), a “second direction” refers to a second horizontal direction (e.g., Y-direction), and the first direction and the second direction may be perpendicular to each other. A “third direction” refers to a vertical direction (e.g., Z-direction), and the third direction may be perpendicular to each of the first direction and the second direction. A horizontal plane or a plane (e.g., X-Y plane) may be a plane defined by the first and second directions. However, as mentioned above, “first,” “second,” etc., may be simply used as a naming convention, and so in the claims and other portions of the specification, a “first direction” may refer to a different direction from the X-direction, etc.

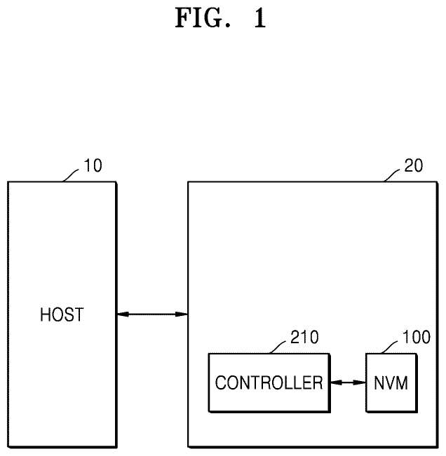

FIG. 1 is a block diagram illustrating a storage system including a semiconductor package according to embodiments.

Referring to FIG. 1, the storage system may include a host device 10 and a storage device 20.

In embodiments, the storage device 20 may be implemented with internal memory embedded in an electronic apparatus, for example, an embedded universal flash storage (UFS) memory device, or an embedded multi-media card (eMMC). In an embodiment, the storage device 20 may be implemented with external memory that is detachable from the electronic apparatus, for example, an UFS memory card, compact flash (CF), secure digital (SD), micro-SD, or mini-SD card, extreme digital (xD), or a memory stick.

The host device 10 may provide a logical address and commands to the storage device 20. During a write operation, the host device 10 may request the storage device 20 to program data to be written into a storage area of non-volatile memory 100 that corresponds to the logical address. During a read operation, the host device 10 may request the storage device 20 to read data from the storage area of the non-volatile memory 100 that corresponds to the logical address.

The storage device 20 may include a storage controller 210 and the non-volatile memory 100. The storage device 20 may be a semiconductor package according to embodiments. A detailed description of an example semiconductor package is provided later.

The storage controller 210 may control overall operation of the storage device 20. Data read from the non-volatile memory 100 may be provided to the host device 10, and the data provided from the host device 10 may be written into the non-volatile memory 100.

The storage controller 210 may control the non-volatile memory 100 to read data stored in the non-volatile memory 100 or to write data into the non-volatile memory 100 in response to a write/read request from the host device 10.

Specifically, the storage controller 210 may provide addresses, commands, and control signals to the non-volatile memory 100, thereby controlling write, read, and erase operations on the non-volatile memory 100. In addition, data to be written to the non-volatile memory 100 and read data to be read from the non-volatile memory may be transmitted and received between the storage controller 210 and the non-volatile memory 100.

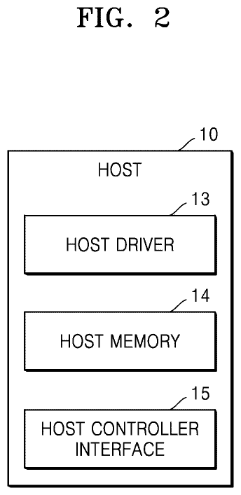

FIG. 2 is a block diagram illustrating the host device 10.

Referring to FIG. 2, the host device 10 may include a host driver 13, host memory 14, and a host controller interface 15. In the present specification, the host device 10 may be a UFS host operating in accordance with a UFS standard.

In some embodiments, the host driver 13 may convert an input/output request generated by an application into UFS commands defined by the UFS standard, and may transmit the UFS commands to the host controller interface 15. A single input/output request may be converted into a plurality of UFS commands. The input/output request may be a task request. The plurality of UFS commands may include UFS protocol information units (UPIU) which follow the UFS standard. The UFS commands may be commands defined by a small computer system interface (SCSI) standard, and may also be commands that are specific to the UFS standard.

The host controller interface 15 may transmit the UFS commands converted by a UFS driver to the storage device 20. In FIG. 2, the host memory 14 is shown as a separate configuration from the host controller interface 15, however, in some embodiments, the host memory 14 may also be included in the host controller interface 15. The host controller interface 15 may control the host memory 14, thereby copying data in a normal area of the host memory 14 (e.g., including data cells) to a cache area of the host memory 14 (e.g., including cache cells). The host controller interface 15 may transmit a logical address (e.g., a logical block address (LBA)) to the storage device 20.

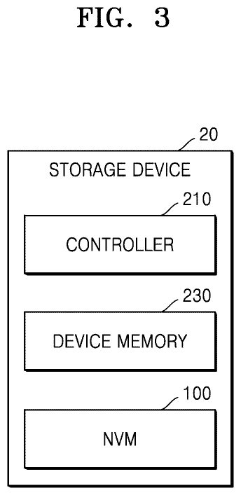

FIG. 3 is a block diagram illustrating the storage device 20 including a semiconductor package according to embodiments. FIG. 3 may be described with reference to FIG. 1.

Referring to FIG. 3, the storage device 20 may include a storage controller 210, device memory 230, and the non-volatile memory 100. A description of the storage controller 210 and the non-volatile memory 100 has been provided with reference to FIG. 1 and thus duplicative details may be omitted.

The device memory 230 may temporarily store data to be written into the non-volatile memory 100 or data read from the non-volatile memory 100. The device memory 230 may include static random access memory (SRAM) or dynamic RAM (DRAM), for example.

The non-volatile memory 100 may include a memory cell array including a plurality of memory cells. For example, the plurality of memory cells may be non-volatile memory cells that retain stored data even when power supply is cut off. Specifically, the non-volatile memory 100 may be electrically erasable programmable read-only memory (EEPROM), flash memory, phase change random access memory (PRAM), resistance random access memory (RRAM), nano floating gate memory (NFGM), polymer random access memory (PoRAM), magneto-resistive random access memory (MRAM), or ferroelectric random access memory (FRAM). Hereinafter, embodiments will be described using an example case where a plurality of memory cells are NAND flash memory cells. However, it should be understood that the technical scope of the inventive concept is not limited to this example.

The memory cell array includes a plurality of memory blocks, and each of the plurality of memory blocks may have a planar structure or a three-dimensional structure. The memory cell array may include at least one of a single level cell block including single level cells (SLCs), a multi-level cell block including multi-level cells (MLCs), a triple level cell block including triple level cells (TLCs), and a quad level cell block including quad level cells (QLCs).

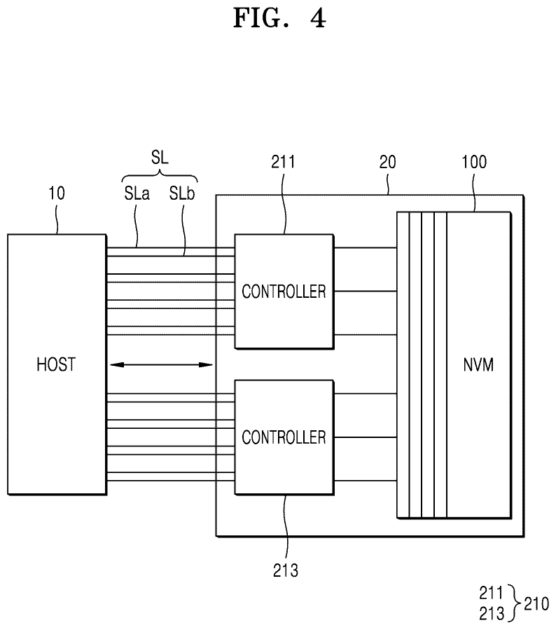

FIG. 4 is a block diagram illustrating a storage system including a semiconductor package according to embodiments. FIG. 4 depicts connection relationship between a host 10, a first controller chip 211, a second controller chip 213, and a non-volatile memory 100, and does not necessarily depict a physical layout of these components.

Referring to FIG. 4, the storage controller 210 of the storage device 20 may include a plurality of controllers such as controller chips, or controller packages including controller chips. The storage controller 210 may include a first controller chip 211 and a second controller chip 213. The first controller chip 211 and the second controller chip 213 may be each connected to the non-volatile memory 100. In some embodiments, a single first controller chip 211 and single second controller chip 213 may be used. In other embodiments, a multi-chip controller device, such as a semiconductor package including a plurality of controller chips, may be used in place of one or both of the first controller chip 211 and the second controller chip 213.

Each of the first controller chip 211 and the second controller chip 213 may be connected to the host device 10 and transmit differential signals using a signal transmission line SL. The signal transmission line SL may be two adjacent signal transmission lines SLa and SLb that form a differential signal line pair and transmit differential signals. The transmission line SLa, which is one of the two signal transmission lines SLa and SLb that form the differential signal line pair, may transmit an input signal, and the other signal line SLb may transmit a complementary signal. The signal transmission line SL may be provided to transmit a high-frequency signal, such as a radio frequency signal ranging from about 6 gigahertz (Ghz) to about 100 Ghz.

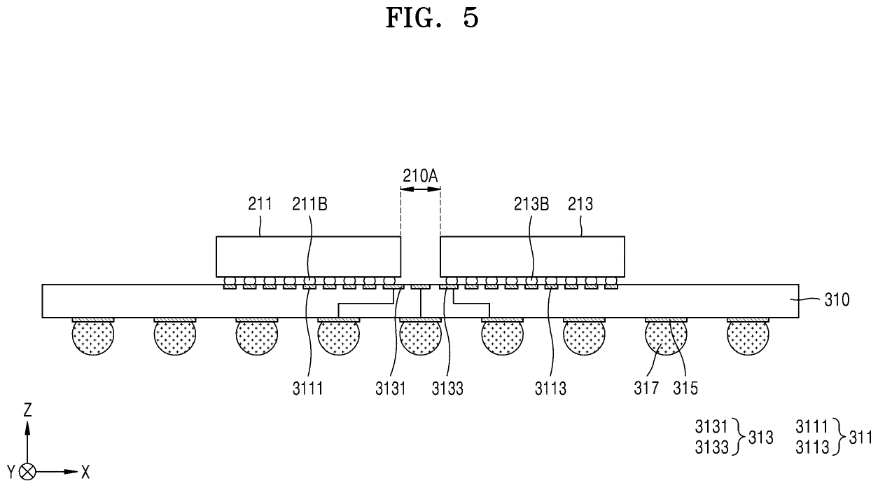

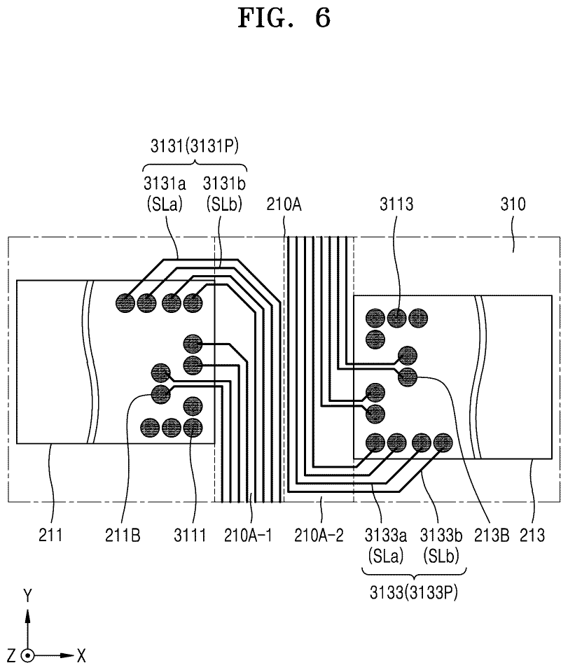

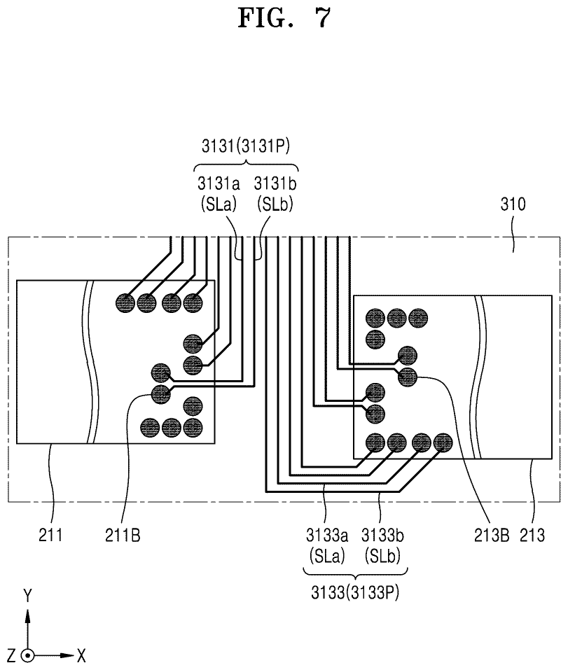

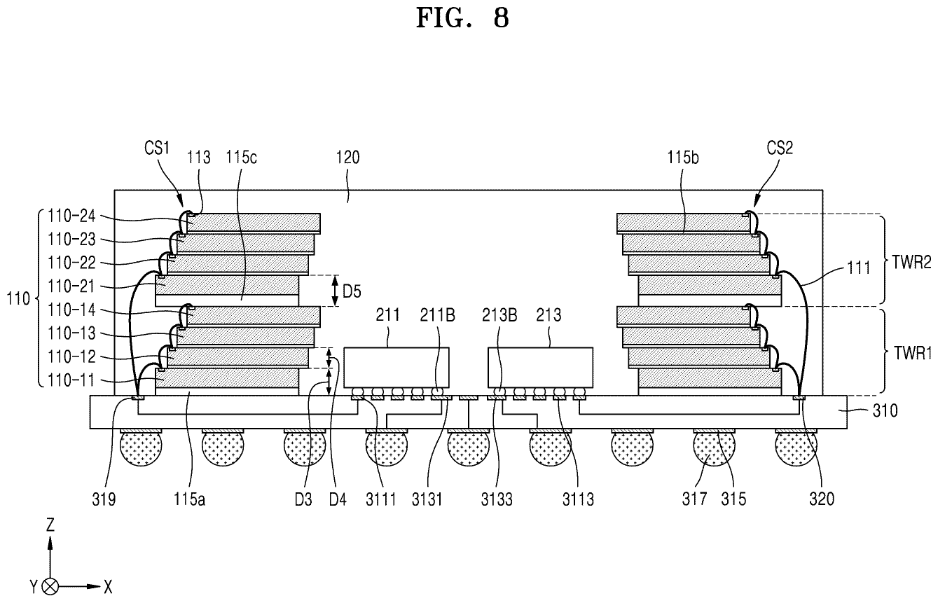

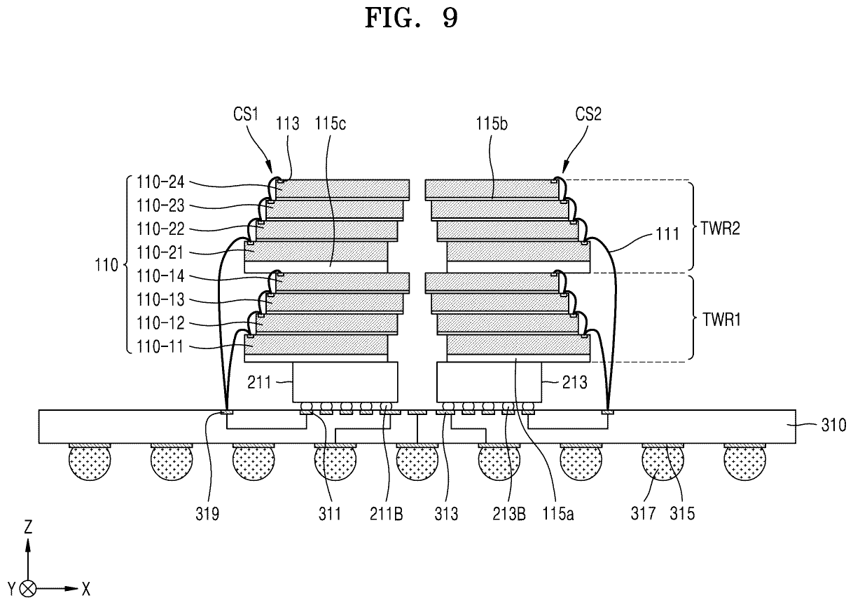

FIG. 5 is a cross-sectional view schematically illustrating part of a semiconductor package according to embodiments, and FIGS. 6 and 7 are plan views schematically illustrating part of a semiconductor package according to embodiments. The nonvolatile memory chips of the semiconductor package are not depicted in FIGS. 5-7 and may be implemented in different manners, such as described in FIGS. 8 and 9, described in more detail below.

Referring to FIG. 5, a semiconductor package according to some embodiments may include a package substrate 310, a plurality of chips, and a plurality of signal line patterns. The plurality of chips may include the first controller chip 211 and the second controller chip 213. For example, the semiconductor package according to embodiments may include two controller chips 211 and 213. Additional chips, such as memory chips, may be formed as part of the package (see, e.g., FIG. 8).

Substrate pads 311 and signal line patterns 313 may be disposed (e.g., formed) on or at an upper surface of the package substrate 310. The substrate pads 311 may include first substrate pads 3111 and second substrate pads 3113, and the signal line patterns 313 may include first signal line patterns 3131 and second signal line patterns 3133. The first substrate pads 3111 and the first signal line patterns 3131 may be connected to the first controller chip 211, and the second substrate pads 3113 and the second signal line patterns 3133 may be connected to the second controller chip 213. The first substrate pads 311 and signal line patterns 313 may be formed of the same material (e.g., a metal or other conductive material) and in the same process, to have the same vertical thickness at a top surface of the package substrate 310.

An external connection pad 315 and an external connection terminal 317 on the external connection pad 315 may be disposed (e.g., formed) on a lower surface of the package substrate 310. The external connection terminal 317 may be, for example, a solder ball. Each of the first signal line patterns 313 may be connected to internal wiring within substrate 310 to connect to a respective external connection pad 315 and external connection terminal 317. The external connection terminals 317 may be used to connect the semiconductor package to a host, such as host 10 of FIG. 4. For example the external connection terminals 317 may be connected to a circuit board (e.g., printed circuit board, or PCB) that connects to the host 10.

The package substrate 310 may be, for example, a PCB and/or a redistribution structure.

In embodiments, the package substrate 310 may be a PCB. The package substrate 310 may include a base layer, and the base layer may include a plurality of subbase layers vertically stacked. An upper surface and a lower surface of the base layer may be covered by a solder resist layer. However, the first substrate pads 3111, the second substrate pads 3113, the first signal line patterns 3131, the second signal line patterns 3133, and the external connection pads 315 may not be covered by the solder resist layer and thus may be exposed on the upper surface and the lower surface of the package substrate 310.

In some embodiments, the base layer may include at least one material selected from a phenol resin, an epoxy resin, and polyimide. For example, the base layer may include at least one selected from the group consisting of flame retardant 4(FR4), tetrafunctional epoxy, polyphenylene ether, epoxy/polyphenylene oxide, bismaleimide triazine (BT), thermount, cyanate ester, polyimide, and liquid crystal polymer.

According to one embodiment, the package substrate 310 is a redistribution structure. The redistribution structure may be a redistribution substrate or redistribution layer including a plurality of redistribution insulating layers, and redistribution patterns provided in the plurality of redistribution insulating layers. The redistribution patterns may include a plurality of redistribution line patterns and a plurality of redistribution via patterns. The plurality of redistribution line patterns may be disposed between the plurality of redistribution insulating layers, and the plurality of redistribution via patterns may extend through the redistribution insulating layers to electrically connect the redistribution line patterns across different layers.

In some embodiments, the redistribution insulating layers may include an insulating material, such as a photo imageable dielectric (PID) resin. In this case, the redistribution insulating layers may further include inorganic fillers. The redistribution patterns may include or be formed of a conductive material such as a metal. For example the redistribution patterns may include or be formed of copper (Cu), aluminum (Al), silver (Ag), tin (Sn), gold (Au), nickel (Ni), lead (Pb), titanium (Ti), or an alloy thereof.

Each of the first controller chip 211 and the second controller chip 213 may control signal transmission between the non-volatile memory (see 100 of FIG. 4) and an external device, and may manage power supplied to the non-volatile memory (see 100 of FIG. 4). For example, each of the first controller chip 211 and the second controller chip 213 may process signals received from a memory chip in the non-volatile memory (see 100 of FIG. 4) and transmit the signals to the external device, and may transmit signals received from the external device to the memory chip in the non-volatile memory (see 100 of FIG. 4).

The first controller chip 211 and the second controller chip 213 may include a plurality of logic devices so as to control signal processing and transmission. For example, each of the first controller chip 211 and the second controller chip 213 may include AND, NAND, OR, NOR, exclusive OR (XOR), exclusive NOR (XNOR), an inverter INV, an adder ADD, a delay DLY, a filter FIL, a multiplexer MXT/MXIT, OR/AND/INVERTER (OAI), AND/OR (AO), AND/OR/INVERTER (AOI), D flip-flop, reset flip-flop, master-slaver flip-flop, latch, a counter, and buffer devices. The logic devices may perform various signal processing such as analog signal processing, analog-to-digital (A/D) conversion, control, and the like.

The first controller chip 211 and the second controller chip 213 may be spaced apart from each other in a first direction (e.g., an X direction) on the package substrate 310. The first controller chip 211 and the second controller chip 213 may be arranged adjacent to each other along the first direction (e.g., the X direction). The first controller chip 211 and the second controller chip 213 may be positioned in or near the center of the package substrate 310, for example in the first direction (e.g., the X direction).

The first controller chip 211 may be mounted on the package substrate 310 in a flip-chip manner, in which the first controller chip 211 is mounted face-down onto the package substrate 310 using first bumps 211B. Some of the first bumps 211B may be connected to respective first substrate pads 3111, while others of the first bumps 211B may be connected to respective first signal line patterns 3131.

The second controller chip 213 may be mounted on the package substrate 310 in the flip-chip manner using second bumps 213B. Some of the second bumps 213B may be connected to respective second substrate pads 3113, while others of the second bumps 213B may be connected to respective second signal line patterns 3133.

Because the first and second controller chips 211 and 213 are mounted face-down in the flip-chip manner, the lower surface of the first controller chip 211 and the lower surface of the second controller chip 213 may be active surfaces of the first and second controller chips 211 and 213 and the upper surface of the first controller chip 211 and the upper surface of the second controller chip 213 may be inactive surfaces of the first and second controller chips 211 and 213.

In an embodiment, a combined first signal line pattern 3131, including two adjacent first signal lines or signal line patterns 3131a and 3131b, may be provided to transmit differential signals between the first controller chip 211 and an external device, such as a host, connected to the corresponding external connection terminals 317. The combined second signal line pattern 3133, including two adjacent second signal lines or signal line patterns 3133a and 3133b, may be provided to transmit differential signals between the second controller chip 213 and an external device connected to the external connection terminals 317.

Referring to FIGS. 5 and 6, two adjacent first signal line patterns 3131a and 3131b of the first signal line patterns 3131 may constitute a first differential signal line pair 3131P. Similarly, two adjacent second signal line patterns 3133a and 3133b of the second signal line patterns 3133 may constitute a second differential signal line pair 3133P. FIG. 6 illustrates that the first signal line patterns 3131 include four first differential signal line pairs 3131P and the second signal line patterns 3133 include four second differential signal line pairs 3133P. However, embodiments are not limited thereto, and the number of the first differential signal line pairs 3131P connected to the first controller chip 211 and the number of the second differential signal line pairs 3133P connected to the second controller chip 213 may be differently designed. For example, the number of the first differential signal line pairs 3131P connected to the first controller chip 211 and the number of the second differential signal line pairs 3133P connected to the second controller chip 213 may be three or less or five or more respectively.

In an embodiment, one signal line pattern 3131a of two first signal line patterns 3131a and 3131b included in the first differential pair 3131P may be configured and connected to transmit an input signal SLa, and the other signal line pattern 3131b of the two first signal line patterns 3131a and 3131b may be configured and connected to transmit a complementary signal SLb. Similarly, one signal line pattern 3133a of two second signal line patterns 3133a and 3133b included in the second differential pair 3133P may be configured and connected to transmit the input signal SLa, and the other signal line pattern 3133b of the two second signal line patterns 3133a and 3133b may be provided to transmit the complementary signal SLb. The input signal SLa and the complementary signal SLb may be differential signals of opposite polarity or phase. In an embodiment, each of the first signal line patterns 3131 and the second signal line patterns 3133 may be connected to transmit a radio frequency signal in a range of about 6 Ghz to about 100 Ghz.

As the semiconductor package according to embodiments includes a plurality of controller chips 211 and 213, more signal line patterns may be used to transmit differential signals between the host 10 and the plurality of controller chips 211 and 213. Additionally, because the two differential signal lines of a differential signal line pair are routed to have substantially same signal delays, the two differential signal lines may have similar routing paths on the package substrate 310. For example, physical lengths of the two different signal lines forming the differential signal line pair may be substantially the same.

According to embodiments, at least part of each of the signal line patterns of the semiconductor package is located in an area (or region) 210A positioned between the first controller chip 211 and the second controller chip 213, and is arranged to extend in a second direction (e.g., the Y direction) within the area 210A. This configuration may increase routing efficiency and wiring density of the semiconductor package, thereby improving data processing performance of the semiconductor package. Some of the signal line patterns of the semiconductor package located in area 210A may also extend in one or more additional directions, such as a diagonal direction with respect to the X direction and Y direction.

Referring to FIGS. 5 and 6, the first controller chip 211 and the second controller chip 213 may be spaced apart from each other in the first direction (e.g., the X direction) to have edges arranged parallel to each other in the second direction (e.g., the Y direction). Accordingly, the area 210A may be a region between the first controller chip 211 and the second controller chip 213, defined by a distance between the first controller chip 211 and the second controller chip 213. The area 210A may include a first area 210A-1 adjacent to the first controller chip and a second area 210A-2 adjacent to the second controller chip. The first signal line patterns may extend along the second direction in the first area 210A-1 and the second signal line patterns may extend along the second direction in the second area 210A-2.

In an embodiment, the first bumps 211B connected to the first signal line patterns 3131 may be arranged on a lower surface of an outer portion of the first controller chip 211 adjacent to the second controller chip 213. The second bumps 213B connected to the second signal line patterns 3133 may be arranged on a lower surface of an outer portion of the second controller chip 213 adjacent to the first controller chip 211. Due to the close spatial arrangement of the first controller chip 211 and the second controller chip 213, the first signal line patterns 3131 and the second signal line patterns 3133 may be arranged adjacent to each other within the area 210A. For efficient routing of the first signal line pattern 3131 and the second signal line pattern 3133 according to embodiments, at least part of the first signal line patterns 3131 included in the semiconductor package extend in the second direction (e.g., the Y direction) in the area 210A between the first controller chip 211 and the second controller chip 213, and at least part of the second signal line patterns 3133 extend in the area 210A between the first controller chip 211 and the second controller chip 213 in the second direction (e.g., the Y direction). As depicted in FIG. 5, a terminal end of each of the signal line patterns may connect to internal wiring within the package substrate 310, which connects to an external connection pad 315 and external connection terminal 317, which may connect to an external device such as a host. The first signal line patterns 3131 and second signal line patterns 3133 may extend in the Y direction in opposite directions from each other, when moving from an end where they connect to a respective controller chip to an opposite, terminal end (e.g., which connects to internal wiring and an external connection terminal 317).

In the area 210A between the first controller chip 211 and the second controller chip 213, one of the first signal line patterns 3131 that is closest to the second controller chip 213 and one of the second signal line patterns 3133 that is closest to the first controller chip 211 may be adjacent to each other in the first direction (e.g., the X direction) and extend in the second direction (e.g., the Y direction). In the area 210A between the first controller chip 211 and the second controller chip 213, the first signal line patterns 3131 and the second signal line patterns 3133 may arranged without alternating placement.

Referring to FIG. 6, in the area 210A between the first controller chip 211 and the second controller chip 213, the first signal line patterns 3131 and the second signal line patterns 3133 may extend in opposite directions along the second direction (e.g., the Y direction). For example, the first signal line patterns 3131 may extend toward a lower region of the area 210A (e.g., −Y direction,) while the second signal line patterns 3133 may extend toward an upper region of the area 210A (e.g., +Y direction). However, embodiments are not limited thereto. For example, as shown in FIG. 7, in the area 210A between the first controller chip 211 and the second controller chip 213, the first signal line patterns 3131 and the second signal line patterns 3133 may extend along the same direction (e.g., the +Y direction or the −Y direction). In the examples of FIGS. 6 and 7, one end of each signal line pattern is connected to a bump 211B or 213B (e.g., a chip bump) and the other end of each signal line pattern is connected to the host 10 (e.g., through an external connection terminal 317). For example, in FIG. 6, signals sent from the first controller chip 211 to the host 10 travel at least for part of the way in the downward direction (e.g., the-Y direction, in a region between a bump 211B of the first controller chip 211 and a bump 213B of the second controller chip 213 along the X direction), and signals sent from the second controller chip 213 to the host 10 travel at least for part of the way in the upward direction (e.g., the +Y direction, in a region between the first controller chip 211 and second controller chip 213 along the X direction). In addition, in the examples of FIGS. 6 and 7, among first signal line patterns 3131 and the second signal line patterns 3133, the first signal line patterns 3131 include a plurality of first differential signal line pairs 3131P, each first differential signal line pair connected to transmit differential signals (SLa and SLb), the second signal line patterns 3133 include a plurality of second differential signal line pairs 3133P, each second differential signal line pair connected to transmit differential signals (SLa and SLb), wherein the first differential signal line pairs are arranged consecutively within the area without any second differential pairs therebetween and the second differential signal line pairs are arranged consecutively within the area without any first differential pairs therebetween.

FIG. 8 is a plan view schematically illustrating a semiconductor package according to embodiments, and FIG. 9 is a plan view schematically illustrating a semiconductor package according to embodiments. The semiconductor packages of FIGS. 8 and 9 may include the wiring and signal line arrangements for differential line pairs such as described above in connection with FIGS. 5-7.

In FIGS. 8 and 9, elements with the same reference numbers as those in FIGS. 5-7, are substantially the same as in FIGS. 5-7, and a redundant description thereof will be omitted and the differences and additional components will be explained instead. Referring to FIG. 8, the semiconductor package according to embodiments may include a first semiconductor chip stack CS1, a second semiconductor chip stack CS2, and a sealant 120.

The first semiconductor chip stack CS1 and the second semiconductor chip stack CS2 may be disposed on a top surface of the semiconductor substrate 310, and may be spaced apart from each other with the first controller chip 211 and the second controller chip 213 therebetween. A distance between the first semiconductor chip stack CS1 and the second semiconductor chip stack CS2 may vary depending on a separation distance between the first controller chip 211 and the second controller chip 213 (see 210A of FIG. 5). The first semiconductor chip stack CS1 and the second semiconductor chip stack CS2 may have a structure symmetrical to each other with respect to the center of the package substrate 310. The first semiconductor chip stack CS1 and the second semiconductor chip stack CS2 may have a structure symmetrical to each other with respect to a virtual center line extending along the second direction (e.g., the Y direction) between the first controller chip 211 and the second controller chip 213. Hereinafter, the first semiconductor chip stack CS1 will be described, and a configuration of the first semiconductor chip stack CS1 may be substantially identical to that of the second semiconductor chip stack CS2.

In an embodiment, the first semiconductor chip stack CS1 may have a two-layer tower structure. For example, the first semiconductor chip stack CS1 may include a first tower TWR1 and a second tower TWR2. The first tower TWR1 may be arranged on the package substrate 310 and may include four memory chips: a first memory chip 110-11, a second memory chip 110-12, a third memory chip 110-13, and a fourth memory chip 110-14. However, the number of memory chips of the first tower TWR1 is not limited to four. For example, the first tower TWR1 may include two, three or five or more memory chips.

The first tower TWR1 may be implemented using a stepped stack structure, so that a portion of the upper surface of the memory chip may be exposed on a side adjacent to an edge of the package substrate 310 from a plan view in the first direction (e.g., the X direction). A chip pad 113 of each of the first through fourth memory chips 110-11 through 110-14 may be arranged on the exposed upper surface. Thus, each of the first through fourth memory chips 110-11 through 110-14 may have an upper surface as an active surface and a lower surface as a non-active surface. In addition, the first through fourth memory chips 110-11 through 110-14 may be mounted on the package substrate 310 using wire bonding. For example, the chip pad 113 of each of the first through fourth memory chips 110-11 through 110-14 may be connected to a first substrate bonding pad 319 (also described as a substrate-to-chip bonding pad) through a bonding wire 111. The first semiconductor chip stack CS1 may be connected to the first controller chip 211 through first internal wiring of the package substrate 310, and the second semiconductor chip stack CS2 may be connected to the second controller chip 213 through second internal wiring of the package substrate 310.

Referring to FIGS. 8 and 9, only a single set of pads, as arranged in the Y direction, is shown. However, in some embodiments, a plurality of additional sets of pads and associated bonding wires (not shown in the cross-sectional view) are be included. Referring to FIG. 8, for the first tower TWR1, only the chip pad 113 of the first memory chip (110-11) of the tower is directly wire-bonded to the first substrate bonding pad 319 (directly wire-bonded referring to being connected using a single bonding wire between two bonding pads), and the chip pad 113 of each of the second to fourth memory chips 110-12 through 110-14 is connected to the first substrate bonding pad 319 via the chip pad 113 of the memory chip(s) arranged under that chip pad 113. However, in some embodiments, the chip pad 113 of one or more of the second through fourth memory chips 110-12 through 110-14 may be directly wire-bonded to the first substrate bonding pad 319 through a separate bonding wire 111.

The first memory chip 110-11 may be disposed and fixed on the package substrate 310 through a first adhesive layer 115a, and each of the second through fourth memory chips 110-12 through 110-14 may be stacked and fixed on the corresponding memory chip disposed thereunder through a second adhesive layer 115b. The first adhesive layer 115a may be thicker than the second adhesive layer 115b. This is to secure the length of the wire 111 for the wire bonding structure of the first memory chip 110-11, for example, to ensure that each wire 111 is long enough for proper bending and bonding to the substrate bonding pad 319 and chip pads 113. For example, the first adhesive layer 115a may have a thickness of about 20 μm, and the second adhesive layer 115b may have a thickness of about 5 μm. Thus, when the thickness of each of memory chips is about 50 μm, a third thickness D3, which is the combined thickness of the first adhesive layer 115a and the first memory chip 110-11, may be about 70 μm, and a fourth thickness D4, which is the combined thickness of the second adhesive layer 115b and one of the second through fourth memory chips 110-12 through 110-14, may be about 55 μm. However, the thickness of the memory chip and the thickness of the second adhesive layers 115a and 115b are not limited to the above-described values.

The second tower TWR2 may be arranged on the first tower TWR1 and may include four memory chips. The second tower TWR2 may include, for example, a first memory chip 110-21, a second memory chip 110-22, a third memory chip 110-23, and a fourth memory chip 110-24. The second tower TWR2 may have substantially the same structure as the first tower TWR1 in that the second tower TWR2 may also have a stepped stack structure, in which the first through fourth memory chips 110-21 through 110-24 may be stacked in a stepped stack configuration that extends upward in the same manner as the first tower TWR1 in the first direction (e.g., the X direction).

The first through fourth memory chips 110-21 through 110-24 of the second tower TWR2 may be mounted on the package substrate 310 using a wire bonding method. The chip pads 113 of each of the first through fourth memory chips 110-21 through 110-24 may be connected to the first substrate bonding pads 319 through one or more wires 111. Because the first tower TWR1 may be disposed between the second tower TWR2 and the package substrate 310 as shown in FIG. 8, among the chip pads 113 of the second tower TWR2, only the chip pad 113 of the first memory chip 110-21 may be directly wire-bonded to the first substrate bonding pad 319 through the bonding wire 111, and the chip pad 113 of each of the second through fourth memory chips 110-22 through 110-24 may be connected to the package substrate 310 via the chip pad(s) 113 of the memory chip(s) disposed therebelow. However, in some embodiments, the chip pad 113 of one or more of the second through fourth memory chips 110-22 through 110-24 of the second tower TWR2 may be directly wire-bonded to the package substrate 310 via the bonding wire 111.

The first memory chip 110-21 of the second tower TWR2 may be stacked and fixed on the fourth memory chip 110-14 of the first tower TWR1 via a third adhesive layer 115c, and each of the second through fourth memory chips 110-22 through 110-24 may be stacked and fixed onto a corresponding lower memory chip using the second adhesive layer 115b. The third adhesive layer 115c may be thicker than each of the first adhesive layer 115a and the second adhesive layer 115b to strengthen the support force of the first memory chip 110-21 and also to secure a minimum wire bonding space between the chip pad 113 of the fourth memory chip 110-14 of the first tower TWR1 and the third memory chip 110-13. For example, the third adhesive layer 115c may have a thickness of about 50 μm. Thus, a fifth thickness D5, which is the combined thickness of the third adhesive layer 115c and the first memory chip 110-21, may be about 100 μm. In some embodiments, the first memory chip 110-21 may have a greater thickness than the other memory chips of the second tower TWR2. For example, the first memory chip 110-21 may have a thickness of about 70 μm, and in this case, the fifth thickness D5 may be about 120 μm. However, the thicknesses of the memory chip and the third adhesive layer 115c are not limited to the above-described values. The third adhesive layer 115c may extend the entire length of the first memory chip 110-21 in some embodiments, but in other embodiments, to avoid the need to bury part of the bonding wires 111 in the third adhesive layer 115c, it may be shortened to end prior to the chip pad 113 of the fourth memory chip 110-14.

Referring to FIG. 8, the first substrate bonding pad 319 corresponding to the first semiconductor chip stack CS1 may be connected to at least one of the first substrate pads 3111 associated with the first controller chip 211, for example through internal wiring within the substrate 310, so that the memory chips of the non-volatile memory 110 of the first semiconductor chip stack CS1 may be connected to the first controller chip 211. The second substrate bonding pad 320 corresponding to the second semiconductor chip stack CS2 may be connected to at least one of the second substrate pads 3113 associated with the second controller chip 213, for example through internal wiring within the substrate 310, so that the memory chips of the non-volatile memory 110 of the second semiconductor chip stack CS2 may be connected to the second controller chip 213. In addition, the external connection terminals 317 formed on the bottom surface of the package substrate 310 may be connected to the first controller chip 211 through first internal wiring of the package substrate 310, and may be connected to the second controller chip 213 through second internal wiring of the package substrate 310.

As the second semiconductor chip stack CS2 has a symmetrical structure with the first semiconductor chip stack CS1, the memory chips of the first tower TWR1 of the first semiconductor chip stack CS1 and the second semiconductor chip stack CS2 may be positioned to be increasingly closer to one another as they extend upward along the vertical direction (e.g., the Z direction). Likewise, the memory chips of the second tower TWR2 of the first semiconductor chip stack CS1 and the second semiconductor chip stack CS2 may be positioned to be increasingly closer to one another as they extend upward in the vertical direction (e.g., the Z direction).

In an embodiment, the memory chip of the first semiconductor chip stack CS1 may be connected to the package substrate 310 using a wire bonding at the left side of the first semiconductor chip stack CS1 in the first direction (e.g., the X direction), and the memory chip of the second semiconductor chip stack CS2 may be connected to the package substrate 310 using a wire bonding at the right side of the second semiconductor chip stack CS2 in the first direction (e.g., the X direction). Alternatively, memory chips of the first and second semiconductor chip stacks may be stacked vertically to fully overlap each other, and may be connected to the package substrate using a through-silicon via (TSV).

The sealant 120 may seal the first semiconductor chip stack CS1 and the second semiconductor chip stack CS2 on the package substrate 310. The sealant 120 may include a thermosetting resin such as an epoxy resin, a thermoplastic resin such as a polyimide, or a resin including a reinforcing material such as an inorganic filler, for example, ABF, FR-4, or BT resin. In addition, the sealant 120 may include a molding material such as an epoxy mold compound (EMC). However, the material of the sealant 120 is not limited to the above-described materials. The sealant 120 may be formed of a material having high thermal conductivity. For example, the sealant 120 may be formed of a high dielectric constant (high-k) material.

Referring to FIG. 9, in the semiconductor package 1 according to embodiments, the first semiconductor chip stack CS1 may be disposed on the first controller chip 211, and the second semiconductor chip stack CS2 may be disposed on the second controller chip 213. The configuration of the first semiconductor chip stack CS1 and the second semiconductor chip stack CS2 of FIG. 9 may be substantially the same as that of the first semiconductor chip stack CS1 and the second semiconductor chip stack CS2 of FIG. 8. In an embodiment, unlike in FIG. 9, at least one of the first semiconductor chip stack CS1 and the second semiconductor chip stack CS2 may be disposed on the first controller chip 211 or the second controller chip 213, and the other one thereof may be directly mounted on the package substrate 310. In an embodiment, a spacer may be additionally disposed between the first adhesive layer 115a and the package substrate 310.

In FIGS. 8 and 9, the first signal line patterns 3131 and the second signal line patterns 3133 such as shown in FIG. 6 or 7 may be provided on an upper surface of the package substrate 310. The first signal line patterns 3131 and the second signal line patterns 3133 may be connected to the first bump 211B and the second bump 213B, respectively, and may be connected to the external connection terminal 317. The first signal line patterns 3131 may be provided to transmit a high-frequency signal such as a radio frequency signal between external devices connected to the first controller 211 and the external connection terminal 317. The second signal line patterns 3133 may be provided to transmit a high-frequency signal such as a radio frequency signal between external devices connected to the second controller chip 213 and the external connection terminal 317. For example, the first and second signal line patterns 3131 and 3133 may transmit differential signals.

Referring to FIGS. 8 and 9 with FIG. 6, the semiconductor package 1 according to embodiments may include the first and second controller chips 211 and 213 so that data processing performance may be enhanced. The first and second controller chips 211 and 213 may be spaced apart in the first direction (e.g., the X direction), and at least part of the first and second signal line patterns 3131 and 3133 may extend in the second direction (e.g., the Y direction) perpendicular to the first direction (e.g., the X direction) in the area 210A between the first and second controller chips 211 and 213. Because the semiconductor package 1 includes a plurality of controller chips 211 and 213, an increased number of signal lines may be provided on the upper surface of the package substrate 310 and may traverse across the area 210A between the first and second controller chips 211 and 213, so that an efficiency of wire routing may be enhanced.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
a first controller on the package substrate;
a second controller on the package substrate and spaced apart from the first controller in a first direction; and
first substrate pads and first signal line patterns at an upper surface of the package substrate and connected to the first controller,
wherein at least part of each signal line pattern of the first signal line patterns extends along a second direction perpendicular to the first direction, in an area between the first controller and the second controller.

2. The semiconductor package of claim 1, further comprising:
second substrate pads and second signal line patterns provided at the upper surface of the package substrate and connected to the second controller,
wherein at least part of each signal line pattern of the second signal line patterns extends in the second direction in the area between the first controller and the second controller.

3. The semiconductor package of claim 2, wherein:
in the area between the first controller and the second controller, one of the first signal line patterns that is most adjacent to the second controller from among the first signal line patterns and one of the second signal line patterns that is most adjacent to the first controller from among the second signal line patterns are adjacent to each other in the first direction.

4. The semiconductor package of claim 3, wherein:
the first signal line patterns include a plurality of first differential signal line pairs, each first signal line differential pair connected to transmit differential signals, and
the second signal line patterns include a plurality of second differential signal line pairs, each second differential signal line pair connected to transmit differential signals.

5. The semiconductor package of claim 4, wherein:
the first differential signal line pairs are arranged consecutively within the area without any second differential signal line pairs therebetween; and
the second differential signal line pairs are arranged consecutively within the area without any first differential signal line pairs therebetween.

6. The semiconductor package of claim 5, further comprising:
a first stack of memory chips on a top surface of the package substrate and connected to the first controller through first internal wiring of the package substrate;
a second stack of memory chips on the top surface of the package substrate and connected to the second controller through second internal wiring of the package substrate; and
a plurality of external connection terminals on a bottom surface of the package substrate, and connected to the first controller and the second controller through third internal wiring of the package substrate.

7. The semiconductor package of claim 1, further comprising
bumps provided on a lower surface of the first controller,
wherein a first set of the bumps are connected to the first substrate pads respectively, and second set of the bumps are connected to the first signal line patterns respectively.

8. The semiconductor package of claim 1, wherein the first signal line patterns are connected to transmit differential signals.

9. The semiconductor package of claim 8, wherein two adjacent first signal line patterns of the first signal line patterns constitute a first differential pair.

10. The semiconductor package of claim 9, wherein one of the first signal line patterns included in the first differential pair is connected to transmit an input signal, and the other is connected to transmit a complementary signal to the input signal.

11. The semiconductor package of claim 1, wherein the first signal line patterns are configured to transmit a radio frequency signal in a range of about 6 Ghz to about 100 Ghz.

12. The semiconductor package of claim 1, further comprising:
external connection terminals provided on a lower surface of the package substrate,
wherein a set of the external connection terminals are electrically connected to the first signal line patterns through internal wiring of the package substrate.

13. The semiconductor package of claim 1, wherein the semiconductor package comprises a universal flash storage (UFS).

14. A semiconductor package comprising:
a package substrate;
a first controller chip and a second controller chip on an upper surface of the package substrate and spaced apart from each other in a first direction;
a first semiconductor chip stack on the upper surface of the package substrate;
a second semiconductor chip stack spaced apart from the first semiconductor chip stack and on the upper surface of the package substrate;
first substrate pads and first signal line patterns at the upper surface of the package substrate and connected to the first controller chip; and
external connection terminals provided on a lower surface of the package substrate and connected to the first signal line patterns,
wherein:
the first semiconductor chip stack comprises two or more first memory chips,
the second semiconductor chip stack comprises two or more second memory chips,
each first memory chip is connected to at least one of the first substrate pads, and
in an area between the first controller chip and the second controller chip, the first signal line patterns extend in a second direction perpendicular to the first direction.

15. The semiconductor package of claim 14, wherein the first semiconductor chip stack and the second semiconductor chip stack are spaced apart from each other with the first controller chip and the second controller chip therebetween.

16. The semiconductor package of claim 14, wherein:
the first semiconductor chip stack is on the first controller chip, and
the second semiconductor chip stack is on the second controller chip.

17. The semiconductor package of claim 14, further comprising:
second substrate pads and second signal line patterns at the upper surface of the package substrate and connected to the second controller chip,
wherein each second memory chip is connected to at least one of the second substrate pads, and
wherein at least some of the second signal line patterns extend in the second direction in the area between the first controller chip and the second controller chip.

18. The semiconductor package of claim 17, wherein:
in the area between the first controller chip and the second controller chip, the first signal line patterns and the second signal line patterns extend from where they connect to a respective controller chip to a terminal end in opposite directions along the second direction.

19. The semiconductor package of claim 17, wherein:
two adjacent first signal line patterns of the first signal line patterns constitute a first differential pair, and two first signal line patterns included in the first differential pair are connected to transmit signals of opposite polarity, and
two adjacent second signal line patterns of the second signal line patterns constitute a second differential pair, and two second signal line patterns included in the second differential pair are connected to transmit signals of opposite polarity.

20. A semiconductor package comprising:
a package substrate;
first and second controller chips mounted on the package substrate in a flip-chip bonding structure through bumps and being adjacent to each other in a first direction;
first and second semiconductor chip stacks spaced apart from each other and from an area between the first controller chip and the second controller chip on the package substrate;
first substrate pads and first signal line patterns at an upper surface of the package substrate and connected to bumps of the first controller chip;
second substrate pads and second signal line patterns at the upper surface of the package substrate and connected to bumps of the second controller chip; and
external connection terminals on a lower surface of the package substrate and connected to the first signal line patterns and the second signal line patterns,
wherein the first signal line patterns and the second signal line patterns are each configured to transmit radio frequency signals in a range of 6 Ghz to 100 Ghz, and
wherein, in the area between the first controller chip and the second controller chip, the first signal line patterns and the second signal line patterns each extend in a second direction perpendicular to the first direction.
